(19) United States
(12) Patent Application Publication
(10) Pub. No.: US 2011/0143055 A1
(43) Pub. Date: Jun. 16, 2011

(54) DISPERSIONS OF POLYURETHANES, THEIR PREPARATION AND USE

(75) Inventors: Holger Tuerk, Mannheim (DE); Reinhold Schwalm, Wachenheim (DE); Cedric Du fresne von hohenesche, GM Almere (NL); Martin Kaarup Bek, Sint Nicolaasga (NL)

(73) Assignee: BASF SE, Ludwigshafen (DE)

(21) Appl. No.: 13/058,200

(22) PCT Filed: Jul. 30, 2009
(86) PCT No.: PCT/EP2009/059895

§ 371 Date: Feb. 9, 2011

(30) Foreign Application Priority Data
Aug. 12, 2008 (EP) 08162200.3

(51) Int. Cl. C09D 11/10; B05D 5/00; C23C 14/22

(52) U.S. Cl. 427/596; 524/589; 524/591; 522/84; 427/256; 427/288; 427/287

(57) ABSTRACT

The present invention provides the use of aqueous dispersions comprising a pigment (B) at least partially enveloped by polyurethane (A) and further comprising at least one polymerization inhibitor (C), said polyurethane (A) being obtainable by reaction of
(a) 15% to 70% by weight of di- or polyisocyanate comprising on average from 1 to 10 allophanate groups and on average from 1 to 10 C—C double bonds per molecule, and optionally
(b) 0% to 60% by weight of further di- or polyisocyanate, with
(c) 5% to 50% by weight of compound having at least two isocyanate-reactive groups,
   weight % ages being based on total polyurethane (A), in printing inks.

The present invention relates to the use of aqueous dispersions comprising a pigment (B) at least partially enveloped by a polyurethane (A) and further comprising at least one polymerization inhibitor (C), said polyurethane (A) being obtainable by reaction of
(a) 15% to 70% by weight of di- or polyisocyanate comprising on average from 1 to 10 allophanate groups and on average from 1 to 10 C—C double bonds per molecule, and optionally
(b) 0% to 60% by weight of further di- or polyisocyanate, with
(c) 5% to 50% by weight of compounds having at least two isocyanate-reactive groups,
   weight % ages being based on total polyurethane (A), with the proviso that the total is 100%, in printing inks.

Such products and their use for ink jet applications are known from international application WO 2008/098972.

It is frequently necessary to disperse pigments in a liquid and, in particular, aqueous medium in order that they may be further processed to form, for example, recording fluids and, in particular, liquid inks or printing inks. Printing inks have to be stable in storage and demonstrate a homogeneous dispersion of the pigments in the ink. In addition, the prints obtained have to meet colorists' requirements, i.e., exhibit brilliance and depth of shade, and have good fastnesses, for example dry rub fastness, light fastness, water fastness and wet rub fastness, if appropriate after aftertreatment such as fixation for example, and good drying.

To ensure particularly good fastnesses such as for example dry rub fastness (wet rub fastness and wash fastness) for printed substrates, prints can be fixed through so-called radiation curing. So-called radiation-curable liquid inks may be employed for this purpose, see for example U.S. Pat. No. 5,623,001 and EP 0 993 495. Radiation-curable ink jet inks typically comprise a material which can be cured by subjecting it to actinic radiation. In addition, a photoinitiator may be included in radiation-curable ink jet inks.

WO 2006/089933 discloses aqueous dispersions comprising radiation-curable polyurethanes comprising allophanate groups, and also the use of said dispersions in ink jet inks. Printing the disclosed ink jet inks and applying actinic radiation gives printed substrates having very good fastnesses. In many cases, however, it is actually not desirable to have to be reliant on actinic radiation to cure the prints. Uniform curing of prints on non-planar substrates presupposes an optimized geometry for the sources of radiation, which is not always ensurable. Thermal curing of the liquid inks disclosed in WO 2006/089933, however, is possible in those cases only in which the liquid inks in question have been produced without stabilizer (free-radical scavenger, polymerization inhibitor). Such liquid inks, in contrast, have a limited shelf life in some cases.

The present invention has for its object to provide printing inks for printing processes which are particularly efficiently curable by the application of actinic radiation and/or thermally and also have a long shelf life.

We have found that this object is achieved by the use of aqueous dispersions defined at the beginning. The use according to the present invention relates to printing inks used in printing processes other than ink jet processes (the inks employed in the latter processes usually being termed “liquid inks”).

Herein the term “liquid ink” is exclusively use for inking liquids for fiber tip pens, fineliners, felt tip pens, fountain pens, markers, highlighters, liquid-ink ball point pens, stamp pads, ink ribbons and particularly ink jet liquid.

By contrast, the term “printing ink” is used herein as a collective designation of colorant-containing preparations of varying consistency which are applied exclusively by means of a printing plate to a printing stock and are fixed there as ink film (print) (CEPE definition).

Polyurethanes shall for the purposes of the present invention be understood as meaning not just such polymers as are exclusively linked by urethane groups but in a more general sense polymers obtainable by reaction of di- or polyisocyanates with compounds comprising active hydrogen atoms. Polyurethanes for the purposes of the present invention thus may comprise urea, allophanate, biuret, carbodiimide, amide, ester, ether, uretoneimine, uretidione, isocyanurate or oxazolidine groups as well as urethane groups. As a general reference there may be cited by way of example: Kunststoffhandbuch/Saechtling, 26th edition, Carl-Hanser-Verlag, Munich 1995, pages 491 et seq. More particularly, polyurethanes for the purposes of the present invention comprise allophanate groups.

In one embodiment of the present invention, the polyurethane (A) is not a hyperbranched polyurethane. Hyperbranched polyurethanes are known as such and are described for example in J. M. S.—Rev. Macromol. Chem. Phys. 1997, C37(3), 555.

Aqueous dispersions according to the present invention comprise a pigment (B) at least partially enveloped by a polyurethane (A).

In what follows, “pigment at least partially enveloped by at least one polyurethane” is to be understood as meaning such a pigment in particulate form whose outer surface is wholly or partly covered by polyurethane (A). Mixtures of pigment in particulate form in each of which a certain percentage of the pigmentary particles is not enveloped by polyurethane (A) and in each of which the outer surface of the other pigmentary particles is wholly or partly covered by polyurethane (A) likewise come within the definition of “pigment at least partially enveloped by a polyurethane (A)”.

Polyurethane (A) may comprise one or more polyurethanes (A). In the case of two or more polyurethanes, numerical data in connection with polyurethane (A) are always based on the totality of polyurethanes (A).

In one embodiment of the present invention, pigment at least partially enveloped by at least one polyurethane (A) has at least 10%, preferably at least 20% and more preferably at least 30% of its outer surface covered by polyurethane (A).

The degree of envelopment can be determined for example by measuring the zeta potential, through microscopic methods such as for example optical microscopy or methods of electron microscopy (TEM, cryo-TEM, SEM) and, quite specifically, with the aid of the freeze fracture preparation technique, NMR spectroscopy or photoelectron spectroscopy on dried at least partially enveloped pigment.

At least partially to be enveloped pigments (B) are obtained in the realm of the present invention by at least partial envelopment of virtually water-insoluble, finely divided, organic or inorganic colorants as per the definition in German standard specification DIN 55944. Aqueous dispersions according to the present invention are preferably produced from organic pigments, which comprises carbon black. White pigments are similarly preferred, in particular titanium dioxide. Examples of particularly suitable pigments (B) will now be recited.

### Organic Pigments:

Monoazo pigments: C.I. Pigment Brown 25; C.I. Pigment Orange 5, 13, 36 and 67; C.I. Pigment Red 1, 2, 3, 5, 8, 9, 12, 17, 22, 23, 31, 48:1, 48:2, 48:3, 48:4, 49, 49:1, 52:1, 52:2, 53, 53:1, 53:3, 57:1, 63, 112, 146, 170, 184, 210, 245 and 251; C.I. Pigment Yellow 1, 3, 73, 74, 65, 97, 151 and 183;
Disazo pigments: C.I. Pigment Orange 16, 34 and 44; C.I. Pigment Red 144, 166, 214 and 242; C.I. Pigment Yellow 12, 13, 14, 16, 17, 81, 83, 106, 113, 126, 127, 155, 174, 176 and 188;
Anthanthrone pigments: C.I. Pigment Red 168 (C.I. Vat Orange 3);
Anthraquinone pigments: C.I. Pigment Yellow 147 and 177; C.I. Pigment Violet 31;
Anthraquinone pigments: C.I. Pigment Yellow 147 and 177; C.I. Pigment Violet 31;
Anthrapyrimidine pigments: C.I. Pigment Yellow 108 (C.I. Vat Yellow 20);
Quinacridone pigments: C.I. Pigment Red 122, 202 and 206; C.I. Pigment Violet 19;
Quinophthalone pigments: C.I. Pigment Yellow 138;
Dioxazine pigments: C.I. Pigment Violet 23 and 37;
Flavanthrone pigments: C.I. Pigment Yellow 24 (C.I. Vat Yellow 1);
Indanthrone pigments: C.I. Pigment Blue 60 (CA. Vat Blue 4) and 64 (C.I. Vat Blue 6);
Isoindoline pigments: C.I. Pigment Orange 69; C.I. Pigment Red 260; C.I. Pigment Yellow 139 and 185;
Isoindolinone pigments: C.I. Pigment Orange 61; C.I. Pigment Red 257 and 260; C.I. Pigment Yellow 109, 110, 173 and 185;
Isoviolanthrone pigments: C.I. Pigment Violet 31 (C.I. Vat Violet 1);
Metal complex pigments: C.I. Pigment Yellow 117, 150 and 153; C.I. Pigment Green 8;
Perinone pigments: C.I. Pigment Orange 43 (C.I. Vat Orange 7); C.I. Pigment Red 194 (C.I. Vat Red 15);
Perylene pigments: C.I. Pigment Black 31 and 32; C.I. Pigment Red 123, 149, 178, 179 (C.I. Vat Red 23), 190 (C.I. Vat Red 29) and 224; C.I. Pigment Violet 29;
Phthalocyanine pigments: C.I. Pigment Blue 15, 15:1, 15:2, 15:3, 15:4, 15:6 and 16; C.I. Pigment Green 7 and 36;
Pyranthrone pigments: C.I. Pigment Orange 51; C.I. Pigment Red 216 (C.I. Vat Orange 4);
Thioindigo pigments: C.I. Pigment Red 88 and 181 (C.I. Vat Red 1); C.I. Pigment Violet 38 (C.I. Vat Violet 3);
Triarylcarbonium pigments: C.I. Pigment Blue 1, 61 and 62; C.I. Pigment Green 1; C.I. Pigment Red 81, 81:1 and 169; C.I. Pigment Violet 1, 2, 3 and 27; C.I. Pigment Black 1 (aniline black);
C.I. Pigment Yellow 101 (aldazine yellow);
C.I. Pigment Brown 22.

### Inorganic Pigments:

White pigments: titanium dioxide (C.I. Pigment White 6), zinc white, pigmented zinc oxide, barium sulfate, zinc sulfide, lithopones; lead white; calcium carbonate;
Black pigments: iron oxide black (C.I. Pigment Black 11), iron-manganese black, spinell black (C.I. Pigment Black 27); carbon black (C.I. Pigment Black 7);
Color pigments: chromium oxide, chromium oxide hydrate green; chromium green (C.I. Pigment Green 48); cobalt green (C.I. Pigment Green 50); ultramarine green; cobalt blue (C.I. Pigment Blue 28 and 36); ultramarine blue; iron blue (C.I. Pigment Blue 27); manganese blue; ultramarine violet; cobalt and manganese violet; iron oxide red (C.I. Pigment Red 101); cadmium sulfoselenide (C.I. Pigment Red 108); molybdate red (C.I. Pigment Red 104); ultramarine red;

Iron oxide brown, mixed brown, spinell and corundum phases (C.I. Pigment Brown 24, 29 and 31), chromium orange;

Iron oxide yellow (C.I. Pigment Yellow 42); nickel titanium yellow (C.I. Pigment Yellow 53; C.I. Pigment Yellow 157 and 164); chromium titanium yellow; cadmium sulfide and cadmium zinc sulfide (C.I. Pigment Yellow 37 and 35); chromium yellow (C.I. Pigment Yellow 34), zinc yellow, alkaline earth metal chromates; Naples yellow; bismuth vanadate (C.I. Pigment Yellow 184);
Interference pigments: metallic effect pigments based on coated metal platelets; pearl luster pigments based on metal oxide coated mica platelets; liquid crystal pigments.

Preferred pigments (B) in this context are monoazo pigments (especially laked BONS pigments, Naphthol AS pigments), disazo pigments (especially diaryl yellow pigments, bisacetoacetanilide pigments, disazopyrazolone pigments), quinacridone pigments, quinophthalone pigments, perinone pigments, phthalocyanine pigments, triarylcarbonium pigments (alkali blue pigments, laked rhodamines, dye salts with complex anions), isoindoline pigments, white pigments and carbon blacks.

Examples of particularly preferred pigments (B) are specifically: carbon black, titanium dioxide, C.I. Pigment Yellow 138, C.I. Pigment Red 122 and 146, C.I. Pigment Violet 19, C.I. Pigment Blue 15:3 and 15:4, C.I. Pigment Black 7, C.I. Pigment Orange 5, 38 and 43 and C.I. Pigment Green 7.

In one embodiment of the present invention, polyurethane (A) has a glass transition temperature, determinable by differential scanning calorimetry (DSC) for example, of not more than 50° C. and preferably of not more than 40° C., determined according to ASTM 3418/82 at a heating rate of 10° C./min.

Polyurethanes (A) for the purposes of the present invention are obtainable by reaction of
(a) 15% to 70% by weight, preferably 30% to 60% by weight, of di- or polyisocyanate comprising on average from 1 to 10 allophanate groups and on average from 1 to 10 C—C double bonds per molecule, average values each preferably being based on the number average, with
(b) nil to 60% by weight, preferably up to 20% by weight, of further di- or polyisocyanate, and
(c) 5% to 50% by weight, preferably 30% to 50% by weight, of compounds having at least two isocyanate-reactive groups.

At least one di- or polyisocyanate (a) which comprises on average from 1 to 10 and preferably up to 5 allophanate groups and on average per molecule from 1 to 10 and preferably up to 5 C—C double bonds per molecule, average values each being based on the weight average and preferably on the number average, is a compound which is preferably prepared in the presence of a catalyst, from at least one diisocyanate (a1) with at least one compound of the general formula I

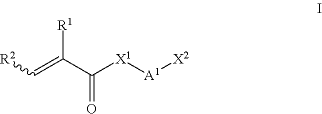

herein also referred to as compound (a2) for short, the variables being defined as follows:
R¹ and R² are the same or different and are independently selected from hydrogen and C₁-C₁₀-alkyl, such as for example methyl, ethyl, n-propyl, iso-propyl, n-butyl, isobutyl, sec-butyl, tert-butyl, n-pentyl, isopentyl, sec-pentyl, neo-pentyl, 1,2-dimethylpropyl, isoamyl, n-hexyl, isohexyl, sec-hexyl, n-heptyl, n-octyl, 2-ethylhexyl, n-nonyl, n-decyl; more preferably C₁-C₄-alkyl such as methyl, ethyl, n-propyl, isopropyl, n-butyl, isobutyl, sec-butyl and tert-butyl, in particular methyl;
X¹ is selected from oxygen and N—R³,
A¹ is selected from C₁-C₂₀-alkylene, preferably C₂-C₁₀-alkylene, for example —CH₂—, —(CH₂)₁₂—, —(CH₂)₁₄—, —(CH₂)₁₆—, —(CH₂)₂₀—, preferably —(CH₂)₂—, —(CH₂)₃—, —(CH₂)₄—, —(CH₂)₅—, —(CH₂)₆—, —(CH₂)₈—, —(CH₂)₁₀—, unsubstituted or singly or multiply substituted by
   C₁-C₄-alkyl, for example methyl, ethyl, n-propyl, isopropyl, n-butyl, isobutyl, sec-butyl or tert-butyl, preferably methyl, phenyl or
   —O—C₁—C₄-alkyl, for example —O—CH₃, —O—C₂H₅, —O-n-C₃H₇, —O—CH(CH₃)₂, —O-n-C₄H₉, —O-sec-C₄H₉, —O—C(CH₃)₃, by way of substituted C₁-C₂₀-alkylene there may be mentioned for example —CH(CH₃)—, —CH(C₂H₅)—, —CH(C₆H₅)—, —CH₂—CH(CH₃)—, cis- and trans-CH(CH₃)—CH(CH₃)—, —(CH₂)—C(CH₃)₂—CH₂—, —CH₂—CH(C₂H₅)—, —CH₂—CH(n-C₃H₇)—, —CH₂—CH(iso-C₃H₇)—,
   wherein substituted or unsubstituted C₁-C₂₀-alkylene one or more nonadjacent CH₂ groups may be replaced by oxygen, examples being —CH₂—O—CH₂—, —(CH₂)₂—O—(CH₂)₂—, —[(CH₂)₂—O]₂—(CH₂)₂—, —[(CH₂)₂—O]₃—(CH₂)₂—.
X² is selected from NH—R³ and preferably oxygen,
R³ is in each occurrence different or preferably the same and selected from hydrogen, phenyl and
   C₁-C₁₀-alkyl such as for example methyl, ethyl, n-propyl, isopropyl, n-butyl, isobutyl, sec-butyl, tert-butyl, n-pentyl, isopentyl, sec-pentyl, neo-pentyl, 1,2-dimethylpropyl, isoamyl, n-hexyl, isohexyl, sec-hexyl, n-heptyl, n-octyl, 2-ethylhexyl, n-nonyl, n-decyl; more preferably C₁-C₄-alkyl such as methyl, ethyl, n-propyl, isopropyl, n-butyl, isobutyl, sec-butyl and tert-butyl, in particular methyl.

Very particularly preferred compounds of the general formula I are 2-hydroxyethyl(meth)acrylate and 3-hydroxypropyl (meth)acrylate, in particular 2-hydroxyethyl(meth)acrylate.

Polyurethane may be prepared in the absence or preferably in the presence of at least one catalyst.

Useful catalysts include for example all catalysts typically used in polyurethane chemistry.

Catalysts typically used in polyurethane chemistry are preferably organic amines, especially tertiary aliphatic, cycloaliphatic or aromatic amines, and Lewis-acidic organic metal compounds.

Useful Lewis-acidic organic metal compounds include for example tin compounds, for example tin(II) salts of organic carboxylic acids, examples being tin(II) acetate, tin(II) octoate, tin(II) ethylhexanoate and tin(II) laurate and the dialkyltin(IV) derivatives of organic carboxylic acids, examples being dimethyltin diacetate, dibutyltin diacetate, dibutyltin dibutyrate, dibutyltin bis(2-ethylhexanoate), dibutyltin dilaurate, dibutyltin maleate, dioctyltin dilaurate and dioctyltin diacetate. Metal complexes such as acetyl acetonates of iron, of titanium of zinc, of aluminum, of zirconium, of manganese, of nickel and of cobalt are possible as well. Further useful metal compounds are described by Blank et al. in Progress in Organic Coatings, 1999, 35, 19 ff.

Preferred Lewis-acidic organic metal compounds are dimethyltin diacetate, dibutyltin dibutyrate, dibutyltin bis(2-ethylhexanoate), dibutyltin dilaurate, dioctyltin dilaurate, zirconium acetylacetonate and zirconium 2,2,6,6-tetramethyl-3,5-heptanedionate.

Similarly, bismuth, zinc and cobalt catalysts and also cesium salts can be used as hydrophilic catalysts. Useful cesium salts include those compounds utilizing the following anions: F⁻, Cl⁻, ClO⁻, ClO₃⁻, ClO₄⁻, Br⁻, J⁻, JO₃⁻, CN⁻, OCN⁻, NO₂⁻, NO₃⁻, HCO₃⁻, CO₃²⁻, S²⁻, SH⁻, HSO₃⁻, SO₃²⁻, HSO₄⁻, SO₄²⁻, S₂O₂²⁻, S₂O₄²⁻, S₂O₅²⁻, S₂O₆²⁻, S₂O₇²⁻, S₂O₈²⁻, H₂PO₂⁻, H₂PO₄⁻, HPO₄²⁻, PO₄³⁻, P₂O₇⁴⁻, (OCₙH₂ₙ₊₁)⁻, (CₙH₂ₙ₋₁O₂)⁻, (CₙH₂ₙ₋₃O₂)⁻ and (Cₙ₊₁H₂ₙ₋₂O₄)²⁻, where n represents integers from 1 to 20.

Preference is given to zinc carboxylates and cesium carboxylates in which the anion conforms to the formulae (CₙH₂ₙ₋₁O₂)⁻ and also (Cₙ₊₁H₂ₙ₋₂O₄)²⁻ where n is from 1 to 20. Particularly preferred cesium salts comprise monocarboxylates of the general formula (CₙH₂ₙ₋₁O₂)—, where n represents integers from 1 to 20, as anions. Formate, acetate, propionate, hexanoate, 2-ethylhexanoate, n-octanoate and neodecanoate must be mentioned in particular here.

As customary organic amines there may be mentioned by way of example: triethylamine, 1,4-diazabicyclo[2,2,2]octane, tributylamine, dimethylbenzylamine, N,N,N′,N′-tetramethylethylenediamine, N,N,N′,N′-tetramethylbutane-1,4-diamine, N,N,N′,N′-tetramethylhexane-1,6-diamine, dimethylcyclohexylamine, dimethyl-dodecylamine, pentamethyldipropylenetriamine, pentamethyldiethylenetriamine, 3-methyl-6-dimethylamino-3-azapentol, dimethylaminopropylamine, 1,3-bisdimethylaminobutane, bis(2-dimethylaminoethyl) ether, N-ethylmorpholine, N-methylmorpholine, N-cyclohexylmorpholine, 2-dimethylaminoethoxyethanol, dimethylethanolamine, tetramethylhexamethylenediamine, dimethylamino-N-methylethanolamine, N-methylimidazole, N-formyl-N,N′-dimethylbutylenediamine, N-dimethylaminoethylmorpholine, 3,3′-bisdimethylamino-di-n-propylamine and/or 2,2′-dipiparazine diisopropyl ether, dimethylpiparazine, tris(N,N-dimethylaminopropyl)-s-hexahydrotriazine, imidazoles such as 1,2-dimethylimidazole, 4-chloro-2,5-dimethyl-1-(N-methylaminoethyl)imidazole, 2-aminopropyl-4,5-dimethoxy-1-methylimidazole, 1-aminopropyl-2,4,5-tributylimidazole, 1-aminoethyl-4-hexylimidazole, 1-aminobutyl-2,5-dimethylimidazole, 1-(3-aminopropyl)-2-ethyl-4-methylimidazole, 1-(3-aminopropyl)imidazole and/or 1-(3-aminopropyI)-2-methylimidazole.

Preferred organic amines are trialkylamines having independently two C₁- to C₄-alkyl radicals and one alkyl or cycloalkyl radical having 4 to 20 carbon atoms, for example dimethyl-C₄-C₁₅-alkylamine such as dimethyldodecylamine or dimethyl-C₃-C₈-cycloalkylamine. Likewise preferred organic amines are bicyclic amines which may if appropriate comprise a further heteroatom such as oxygen or nitrogen such as for example 1,4-diazabicyclo[2,2,2]octane.

It is particularly preferable to use ammonium acetate or triethylamine and most preferable to use N,N,N-trimethyl-N-(2-hydroxypropyl)ammonium 2-ethyihexanoate.

It will be appreciated that mixtures of two or more of the aforementioned compounds may be used as catalysts as well.

Particular preference is given to using such catalysts selected from the aforementioned compounds as are soluble in organic solvents such as acetone, tetrahydrofuran (THF), N-methylpyrrolidone and/or N-ethylpyrrolidone.

Catalyst is preferably used in an amount from 0.0001% to 10% by weight and more preferably in an amount from 0.001% to 5% by weight, based on diisocyanate (a1).

The catalyst or catalysts may be added in solid or liquid form or in solution, depending on the constitution of the catalyst or catalysts. Useful solvents include water-immiscible solvents such as aromatic or aliphatic hydrocarbons such as for example toluene, ethyl acetate, hexane and cyclohexane and also carboxylic esters such as for example ethyl acetate, useful solvents further including acetone, THF and N-methylpyrrolidone and N-ethylpyrrolidone. The catalyst or catalysts is or are preferably added in solid or liquid form and most preferably in solution in organic solvents such as acetone, tetrahydrofuran (THF), N-methylpyrrolidone or N-ethylpyrrolidone.

Diisocyanate (a1) is selected for example from aliphatic, aromatic and cycloaliphatic diisocyanates. Examples of aromatic diisocyanates are 2,4-tolylene diisocyanate (2,4-TDI), 2,4′-diphenylmethane diisocyanate (2,4′-MDI) and so-called TDI mixtures (mixtures of 2,4-tolylene diisocyanate and 2,6-tolylene diisocyanate).

Examples of aliphatic diisocyanates are 1,4-butylene diisocyanate, 1,12-dodeca-methylene diisocyanate, 1,10-decamethylene diisocyanate, 2-butyl-2-ethylpenta-methylene diisocyanate, 2,4,4-trimethylhexamethylene diisocyanate or 2,2,4-trimethyl-hexamethylene diisocyanate and in particular hexamethylene diisocyanate (HDI).

Examples of cycloaliphatic diisocyanates are isophorone diisocyanate (IPDI), 2-isocyanatopropylcyclohexyl isocyanate, 2,4′-methylenebis(cyclohexyl)diisocyanate and 4-methylcyclohexane 1,3-diisocyanate (H-TDI).

Further examples of isocyanates having groups of differing reactivity are 1,3-phenylene diisocyanate, 1,4-phenylene diisocyanate, 1,5-naphthylene diisocyanate, diphenyl diisocyanate, tolidine diisocyanate and 2,6-tolylene diisocyanate.

Mixtures of the aforementioned diisocyanates can be used, of course.

Diisocyanate (a1) and compound (a2) can be employed in molar ratios of for example from 10:1 to 1:1 and preferably from 5:1 to 5:4.

In one embodiment of the present invention, diisocyanate (a1) and compound (a2) can be reacted with each other at temperatures in the range from 20° C. to 150° C. and preferably from 50 to 130° C.

In one embodiment of the present invention, diisocyanate (a1) and compound (a2) can be in solvent, preferably in an organic solvent or a mixture of organic solvents such as for example toluene, acetone or tetrahydrofuran or mixtures thereof. In another embodiment of the present invention, the reaction of diisocyanate (a1) with compound (a2) is carried out without use of solvent.

In one embodiment of the present invention, the reaction conditions for the reaction of diisocyanate (a1) with compound (a2), for example the molar ratios of diisocyanate (a1) and compound (a2), are chosen such that diisocyanate (a) has 2 isocyanate groups and from 1 to 10 allophanate groups and from 1 to 10 C—C double bonds but no O—CO—NH groups. In another embodiment of the present invention, the reaction conditions for the reaction of diisocyanate (a1) with compound (a2), for example the molar ratios of diisocyanate (a1) and compound (a2), are chosen such that diisocyanate (a) has 2 isocyanate groups and from 1 to 9 allophanate groups and from 1 to 9 C—C double bonds and also one or more O—CO—NH groups.

After the reaction of diisocyanate (a1) with compound (a2) has ended, di- or polyisocyanate (a) can be isolated, for example by removing unconverted starting materials such as diisocyanate (a1) or compound (a2). A suitable method of removing unconverted starting materials such as diisocyanate (a1) and compound (a2) is to distill them out, preferably at reduced pressure. Thin film evaporators are very particularly suitable. Unconverted diisocyanate (a1) is preferably not removed by distillation.

In one embodiment of the present invention, di- or polyisocyanate (a) has a dynamic viscosity at 23° in the range from 500 to 2000 mPa·s, preferably in the range from 600 to 1800 mPa·s and most preferably in the range from 700 to 1500 mPa·s.

In one embodiment of the present invention, di- or polyisocyanate (a) has an NCO content in the range from 8% to 20% by weight and preferably in the range from 12% to 17% by weight, determinable by titration for example.

Polyurethane (A) is prepared by reacting di- or polyisocyanate (a) with at least one further di- or polyisocyanate (b). Di- or polyisocyanate (b) can be selected from the abovementioned aliphatic, aromatic and cycloaliphatic diisocyanates.

In one embodiment of the present invention, di- or polyisocyanate (b) is chosen so that it is other than diisocyanate (a1).

In one embodiment of the present invention, di- or polyisocyanate (b) is chosen so that it is like diisocyanate (a1). One specific embodiment of the present invention comprises selecting di- or polyisocyanate (b) to be like diisocyanate (a1) by not separating from unconsumed diisocyanate (a1) after the preparation of di- or polyisocyanate (a) has ended.

Polyurethane (A) is further prepared by reacting with at least one compound having at least two isocyanate-reactive groups (c) which is also referred to as compound (c) in the realm of the present invention. Particularly readily isocyanate-reactive groups include for example the SH group, the hydroxyl group, the NH₂ group and the NHR³ group, in which R³ is as defined above.

Compound (c) may be hydrophilic or hydrophobic.

At least one compound (c) is preferably selected from 1,1,1-trimethylol-C₁-C₄-alkyl-carboxylic acids, for example 1,1,1-trimethylol acetic acid, 1,1,1-trimethylolpropanoic acid, 1,1,1-trimethylolbutyric acid, citric acid, 2,2-dimethylol-C₁-C₄-alkylcarboxylic acids, for example 2,2-dimethylolacetic acid, 2,2-dimethyloipropanoic acid, 2,2-dimethylol-butyric acid, 2,2-dimethylol-C₁-C₄-alkylsulfonic acids, poly-C₂-C₃-alkylene glycols having on average from 3 to 300 alkylene oxide units per molecule, in particular polyethylene glycol having on average (number average) from 3 to 300 ethylene oxide units per molecule and polyaddition products of ethylene oxide and propylene oxide having on average (number average) from 3 to 300 ethylene oxide units per molecule and a molar fraction of ethylene oxide higher than the fraction of propylene oxide;

hydrophilic diamines having COOM or SO₃M groups, for example

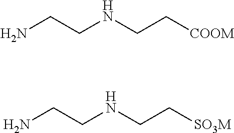

Where each M is selected from alkali metal ions, in particular Na⁺, and ammonium ions,

polyesterdiols preparable by polycondensation of

at least one aliphatic or cycloaliphatic diol, preferably ethylene glycol, 1,4-butanediol, 1,6-hexanediol, cis-1,4-cyclohexanediol, trans-1,4-cyclohexanediol, cis- and trans-1,4-dihydroxymethylcyclohexane (cyclohexanedimethanol), with at least one aliphatic, aromatic or cycloaliphatic dicarboxylic acid, examples being succinic acid, glutaric acid, adipic acid, cyclohexane-1,4-dicarboxylic acid, terephthalic acid, isophthalic acid.

One embodiment of the present invention comprises selecting at least two dicarboxylic acids for preparing polyesterdiol of which one is aromatic and the other is aliphatic, examples being succinic acid and isophthalic acid, glutaric acid and isophthalic acid, adipic acid and isophthalic acid, succinic acid and terephthalic acid, glutaric acid and terephthalic acid, adipic acid and terephthalic acid.

To prepare polyesterdiol using two or more dicarboxylic acids, any desired molar ratios can be used. When an aromatic dicarboxylic acid and an aliphatic dicarboxylic acid are to be used, a molar ratio in the range from 10:1 to 1:10 is preferred, a molar ratio in the range from 1.5:1 to 1:1.5 is peculiar.

In one embodiment of the present invention, polyesterdiols used as compound (c) have a hydroxyl number in the range from 20 to 200 mg KOH/g, preferably in the range from 50 to 180 and most preferably in the range from 100 to 160 mg KOH/g, determined according to German standard specification DIN 53240.

In one embodiment of the present invention, polyesterdiols used as compound (c) have a molecular weight M_{w} in the range from 500 to 100 000 g/mol, preferably in the range from 700 to 50 000 g/mol and more preferably up to 30 000 g/mol.

Further suitable compounds (c) are ethanolamine, diethanolamine, neopentyl glycol, 1,4-butanediol, 1,6-hexanediol, 1,1-dimethylolpropane.

One embodiment of the present invention comprises reacting with at least two compounds (c) of which one is selected from ethanolamine, diethanolamine, neopentylglycol, 1,4-butanediol, 1,6-hexanediol, 1,1-dimethylolpropane.

One embodiment of the present invention comprises synthesizing polyurethane (A) by (d) further adding at least one compound of the general formula I in the reaction of

di- or polyisocyanate (a), and further di- or polyisocyanate (b), if present, with compound (c).

Compounds of the formula I are described above.

As compound (d) of the general formula I there may be used a compound of the general formula I other than for preparing di- or polyisocyanate (a) which on average comprises from 1 to 10 allophanate groups and on average from 1 to 10 C—C double bonds per molecule. Preferably, however, compound (d) and compound (a2) are identical.

The synthesis of polyurethane (A) can be carried out by conventional methods of polyurethane chemistry.

Aqueous dispersions of the present invention further comprise at least one polymerization inhibitor (C), also referred to as inhibitor (C) or stabilizer (C). Polymerization inhibitors (C) can be selected from UV absorbers and free-radical scavengers. UV absorbers convert UV radiation into thermal energy. Suitable UV absorbers include for example oxanilides, triazines and benzotriazole (the latter obtainable as Tinuvin® products from Ciba-Spezialitätenchemie), benzophenones, hydroxybenzophenones, hydroquinone, hydroquinone monoalkyl ethers such as for example hydroquinone monomethyl ether (MEHQ). Free-radical scavengers bind free-radicals formed as intermediates. Suitable free-radical scavengers include for example sterically hindered amines known as Hindered Amine Light Stabilizers (HALSs). Examples thereof are 2,2,6,6-tetramethylpiperidine, 2,6-di-tert-butylpiperidine or derivatives thereof, for example bis(2,2,6,6-tetramethyl-4-piperidyl) sebacate. Further useful polymerization inhibitors (C) are substituted phenols, particularly tert-alkyl-substituted phenols such as for example

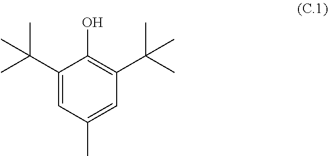

One embodiment of the present invention utilizes a mixture of two or more polymerization inhibitors (C), for example a hydroquinone ether and a substituted phenol.

For example, altogether up to 15% by weight, based on the sum total of (A) and (B), of polymerization inhibitor (C) can be added, more preferably from 0.1 to 1% by weight.

Polymerization inhibitor (C) can be added during the synthesis of polyurethane (A) or subsequently, for example in the course of the dispersing of pigment (B).

One embodiment of the present invention may utilize di- or polyisocyanate (a), further di- or polyisocyanate (b) and compound (c) and optionally further compound of the general formula I (d) in the following weight ratios, each based on total polyurethane (A):

15% to 70% by weight, preferably 30% to 60% by weight, of di- or polyisocyanate (a), nil to 60% by weight, preferably to 20% by weight, of further di- or polyisocyanate (b), 5% to 50% by weight, preferably 30% to 50% by weight, of compound (c), nil to 20% by weight, preferably to 10% by weight, of compound of the general formula I (d).

Each weight % age is based on total polyurethane (A).

One preferred version of the present invention comprises preparing polyisocyanate (A) by reacting not only di- or polyisocyanate (a), further di- or polyisocyanate (b) and compound (c) and if appropriate further compound of the general formula I (d) but additionally with at least one nucleophilic alcohol or amine, preferably monoalcohol or monoamine, which in either case may serve as a stopper and hereinafter is designated stopper (e). Examples of suitable stoppers (e) are mono- and di-C₁-C₄-alkylamines, in particular diethylamine and N,N-diethanolamine. Up to 10% by weight of stopper (e) can be used, based on polyurethane (A) to be synthesized.

The preparation of polyurethane (A) from di- or polyisocyanate (a), further di- or polyisocyanate (b), compound (c) and if appropriate further compound of the general formula I (d) and if appropriate stopper (e) can be carried out in one or more stages.

For example, di- or polyisocyanate (a), further di- or polyisocyanate (b) and compound (c) can be reacted in a first stage, preferably in the presence of a catalyst, the reaction stopped and thereafter again di- or polyisocyanate (b) and compound of the general formula I (d) and if appropriate stopper (e) added. It is also possible for example to react di- or polyisocyanate (a), further di- or polyisocyanate (b) and compound (c) with one another using an excess of further di- or polyisocyanate (b), and to stop the reaction by adding stopper (e).

In one embodiment of the present invention, di- or polyisocyanate (a), further di- or polyisocyanate (b), compound (c) and if appropriate further compound of the general formula I (d) and if appropriate stopper (e) can be reacted in a solvent, preferably in an organic solvent or a mixture of organic solvents such as for example toluene, acetone or tetrahydrofuran or mixtures thereof. In another embodiment of the present invention the reaction of di- or polyisocyanate (a), further di- or polyisocyanate (b), compound (c) and if appropriate further compound of the general formula I (d) and if appropriate stopper (e) is carried out without use of solvent.

One embodiment of the present invention comprises reacting di- or polyisocyanate (a), further di- or polyisocyanate (b) and compound (c) and if appropriate further compound of the general formula I (d) and if appropriate stopper (e) with one another at temperatures in the range from 20° C. to 150° C. and preferably in the range from 20 to 80° C.

To speed up the reaction of di- or polyisocyanate (a), further di- or polyisocyanate (b), compound (c) and if appropriate further compound of the general formula I (d) and if appropriate stopper (e), one or more catalysts can be used which is or are advantageously chosen from the aforementioned catalysts.

After the reaction of di- or polyisocyanate (a), further di- or polyisocyanate (b), compound (c) and if appropriate further compound of the general formula I (d) and if appropriate stopper (e) has ended, polyurethane (A) can be isolated, for example by removing unconverted starting materials such as di- or polyisocyanate (b), compound (c) and if appropriate further compound of the general formula I (d) and if appropriate stopper (e). A suitable method of removing unconverted starting materials such as (b) and (c) and if appropriate (d) and (e) is to distill them out, preferably at reduced pressure. Thin film evaporators are very particularly suitable. Preferably, unconverted di- or polyisocyanate (b) is not distilled out.

The molecular weight M_{w} of the polyurethanes (A) can be for example in the range from 500 to not more than 50 000 g/mol, preferably in the range from 1000 to 30 000 g/mol, more preferably in the range from 2000 to 25 000 g/mol and most preferably at least 2000 g/mol, determined by gel permeation chromatography (GPC) for example.

In a preferred embodiment of the present invention, polyurethane (A) comprises no free NCO groups.

After the reaction of di- or polyisocyanate (a), further di- or polyisocyanate (b) and compound (c) and if appropriate (d) and if appropriate stopper (e) has taken place, water can be added, for example in a weight ratio of polyurethane (A) to water in the range from 1:1 to 1:10.

After the reaction of di- or polyisocyanate (a), further di- or polyisocyanate (b) and compound (c) and if appropriate (d) and stopper (e) has taken place, groups comprising sufficiently acidic hydrogen atoms can be treated with bases to convert them into the corresponding salts. Useful bases include for example hydroxides and bicarbonates of alkali metals or alkaline earth metals or the carbonates of alkali metals. Useful bases further include volatile amines, i.e., amines having a boiling point of up to 180° C. at atmospheric pressure, examples being ammonia, methylamine, dimethylamine, trimethylamine, ethylamine, diethylamine, triethylamine, ethanolamine, N-methyldiethanolamine or triethanolamine. Similarly, basic groups can be converted with acids such as for example α-hydroxy carboxylic acids or α-amino acids or else α-hydroxy sulfonic acids into the corresponding salts.

After the reaction of di- or polyisocyanate (a), further di- or polyisocyanate (b) and compound (c) if appropriate (d) and stopper (e) has taken place, any organic solvent used can be separated off, for example by distillation.

After polyurethane (A) has been prepared, one or more pigments (B) and if appropriate water are optionally added. It is preferable to set a solids content in the range from to 10% to 80%, preferably to 65% and more preferably in the range from 40% to 60%.

The weight ratio of polyurethane (A) to pigment (B) can vary within wide limits. In one embodiment of the present invention, the weight ratio of polyurethane (A) to pigment (B) is in a range from 5:1 to 1:10, preferably from 3:1 to 1:8 and more preferably from 1:1 to 1:6.

Polyurethane (A) and pigment (B) are subsequently dispersed. The dispersing can be effected in any apparatus suitable for dispersing. Shaking apparatuses such as for example from Skandex may be mentioned by way of example. Preferably, polyurethane (A) and pigment (B) are dispersed for example in ultrasonic apparatuses, high pressure homogenizers, 2-, 3-, 4- or 5-roll mills, minimills, Henschel mixers, shaking mills, Ang mills, gear mills, bead mills, wet mills, sand mills, attritors, colloid mills, ultrasonic homogenizers, with Ultra Turrax stirrer and in particular by grinding, for example in 2-, 3-, 4- or 5-roll mills, minimills, shaking mills, Ang mills, gear mills, bead mills, wet mills, sand mills, colloid mills, ball mills, specifically stirred ball mills.

The dispersing time is suitably in the range from 10 minutes to 48 hours for example, although a longer time is conceivable as well. Preference is given to a dispersing time in the range from 15 minutes to 24 hours.

Pressure and temperature conditions during the dispersing are generally not critical in that for example atmospheric pressure has been found to be suitable. As temperatures, for example temperatures in the range from 10° C. to 100° C. have been found to be suitable, preferably up to 80° C.

The dispersing provides aqueous dispersion according to the present invention. In one embodiment of the present invention, aqueous dispersions according to the present invention have a solids content in the range from 10% to 80%, preferably up to 65% and more preferably in the range from 40% to 60%.

Customary grinding aids can be added during the dispersing.

The average diameter of pigment (B) at least partially enveloped by polyurethane (A) is typically in the range from 20 nm to 1.5 μm, preferably in the range from 60 to 500 nm and more preferably in the range from 60 to 350 nm after the dispersing and in connection with the present invention generally signifies the volume average. Useful measuring appliances for determining the average particle diameter include for example Coulter Counters, for example Coulter LS 230.

When it is desired to use carbon black according to the present invention as pigment (B), the particle diameter is based on the average diameter of the primary particles.

Aqueous dispersions according to the present invention comprise no thermal initiator, i.e., no compound which has a half-life of at least one hour at 60° C. and splits into free radicals in the process, examples being peroxides, hydroperoxides, hydrogen peroxide, persulfates, azo compounds such as for example azobisisobutyronitrile (AIBN) or water-soluble AIBN derivatives, highly substituted, in particular hexasubstituted, ethane derivatives or redox catalysts.

In one embodiment of the present invention, aqueous dispersions according to the present invention comprise at least one polyurethane (D). Polyurethane (D) is obtainable for example by reaction of di- or polyisocyanate (b) with compound (c), but preferably comprises no allophanate groups. Particularly preferably pigment (B) is at least partially enveloped not just by polyurethane (A) but also by polyurethane (D).

In one embodiment of the present invention, aqueous dispersions according to the present invention comprise polyurethane (A) and polyurethane (D) in the range from 10:1 to 1:2 and preferably in the range from 8:1 to 1:1 (weight ratio).

In one embodiment of the present invention, aqueous dispersions according to the present invention comprise at least one photoinitiator (E). Photoinitiator (E) can be added either before the dispersing or alternatively after the dispersing.

Suitable photoinitiators (E) include for example photoinitiators known to one skilled in the art, examples being those mentioned in “Advances in Polymer Science”, Volume 14, Springer Berlin 1974 or in K. K. Dietliker, Chemistry and Technology of UV- and EB-Formulation for Coatings, Inks and Paints, Volume 3; Photoinitiators for Free Radical and Cationic Polymerization, P. K. T. Oldring (Eds), SITA Technology Ltd, London.

Useful photoinitiators include for example mono- or bisacylphosphine oxides as described for example in EP-A 0 007 508, EP-A 0 057 474, DE-A 196 18 720, EP-A 0 495 751 and EP-A 0 615 980, examples being 2,4,6-trimethylbenzoyldiphenylphosphine oxide, ethyl 2,4,6-trimethylbenzoylphenylphosphinate, bis(2,4,6-trimethylbenzoyl)phenylphosphine oxide, benzophenone, hydroxyacetophenone, phenylglyoxylic acid and derivatives thereof or mixtures of the aforementioned photoinitiators. As examples there may be mentioned benzophenone, acetophenone, acetonaphthoquinone, methyl ethyl ketone, valerophenone, hexanophenone, α-phenylbutyrophenone, p-morpholinopropiophenone, dibenzosuberone, 4-morpholinobenzophenone, 4-morpholinodeoxybenzoin, p-diacetylbenzene, 4-aminobenzophenone, 4′-methoxyacetophenone, β-methylanthraquinone, tert-butylanthraquinone, anthraquinonecarboxylic esters, benzaldehyde, α-tetralone, 9-acetylphenanthrene, 2-acetylphenanthrene, 10-thioxanthenone, 3-acetylphenanthrene, 3-acetylindole, 9-fluorenone, 1-indanone, 1,3,4-triacetylbenzene, thioxanthen-9-one, xanthen-9-one, 2,4-dimethylthioxanthone, 2,4-diethylthioxanthone, 2,4-di-iso-propylthioxanthone, 2,4-dichlorothioxanthone, benzoin, benzoin isobutyl ether, chloroxanthenone, benzoin tetrahydropyranyl ether, benzoin methyl ether, benzoin ethyl ether, benzoin butyl ether, benzoin isopropyl ether, 7-H-benzoin methyl ether, benz[de]anthracen-7-one, 1-naphthaldehyde, 4,4′-bis(dimethylamino)benzophenone, 4-phenylbenzophenone, 4-chlorobenzophenone, Michler's ketone, 1-acetonaphthone, 2-acetonaphthone, 1-benzoylcyclohexan-1-ol, 2-hydroxy-2,2-dimethylacetophenone, 2,2-dimethoxy-2-phenylacetophenone, 2,2-diethoxy-2-phenylacetophenone, 1,1-dichloroacetophenone, 1-hydroxyacetophenone, acetophenone dimethyl ketal, o-methoxybenzophenone, triphenylphosphine, tri-o-tolylphosphine, benz[a]anthracene-7,12-dione, 2,2-diethoxyacetophenone, benzil ketals, such as benzil dimethyl ketal, 2-methyl-1-[4-(methylthio)phenyl]-2-morpholinopropan-1-one, anthraquinones such as 2-methylanthraquinone, 2-ethylanthraquinone, 2-tert-butylanthraquinone, 1-chloroanthraquinone, 2-amylanthraquinone and 2,3-butanedione.

Also suitable are nonyellowing or minimally yellowing photoinitiators of the phenylglyoxalic ester type, as described in DE-A 198 26 712, DE-A 199 13 353 or WO 98/33761.

Preferred photoinitiators (E) include for example photoinitiators which split upon activation, so-called α-splitters such as for example photoinitiators of the benzil dialkyl ketal type such as for example benzil dimethyl ketal. Further examples of useful α-splitters are derivatives of benzoin, isobutyl benzoin ether, phosphine oxides, especially mono- and bisacylphosphine oxides, for example benzoyldiphenylphosphine oxide, 2,4,6-trimethylbenzoyldiphenylphosphine oxide, α-hydroxyalkylacetophenones such as for example 2-hydroxy-2-methylphenylpropanone (E.1),

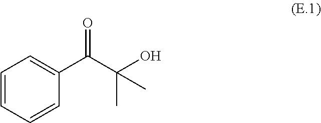

2-hydroxy-1-[4-(2-hydroxyethoxy)phenyl]-2-methyl-1-propanone (E.2)

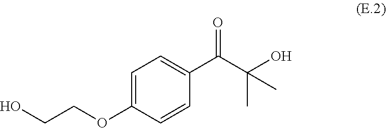

phosphine sulfides and ethyl 4-dimethylaminobenzoate and also (E.3)

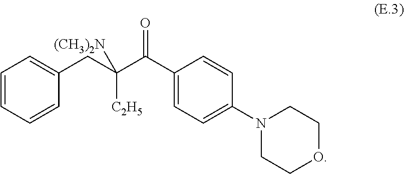

Preferred photoinitiators (E) further include for example hydrogen-abstracting photoinitiators, for example of the type of the substituted or unsubstituted acetophenones, anthraquinones, thioxanthones, benzoic esters or of the substituted or unsubstituted benzophenones. Particularly preferred examples are isopropylthioxanthone, benzophenone, phenyl benzyl ketone, 4-methylbenzophenone, halomethylated benzophenones, anthrone, Michler's ketone (4,4′-bis-N,N-dimethylaminobenzophenone), 4-chlorobenzophenone, 4,4′-dichlorobenzophenone, anthraquinone.

In one embodiment of the present invention, sufficient photoinitiator (E) is added to aqueous dispersions according to the present invention that the weight ratio of polyurethane (A) to photoinitiator (E) is in a range from 2:1 to 5000:1, preferably from 3:1 to 1000:1 and most preferably in a weight ratio from 5:1 to 500:1.

The efficacy of photoinitiators (E) in aqueous dispersions according to the present invention can if desired be enhanced by the addition of at least one synergist, for example of at least one amine, especially of at least one tertiary amine. Useful amines include for example triethylamine, N,N-dimethylethanolamine, N-methylethanolamine, triethanolamine, amino acrylates such as for example amine-modified polyether acrylates. When amines such as for example tertiary amines have been used as a catalyst in the synthesis of polyurethane (A) and have not been removed after synthesis, it is also possible for tertiary amine used as a catalyst to act as a synergist. Furthermore, tertiary amine used to neutralize acidic groups such as for example COOH groups or SO₃H groups can act as a synergist. Up to twice the molar amount of synergist can be added, based on photoinitiator (E) used.

Dispersions according to the present invention may be additized with one or more further compounds having C—C double bonds (F), hereinafter also referred to as unsaturated compounds (F).

In the simplest case, further polyurethanes (A) comprising double bonds are added to the pigment dispersions.

Particularly suitable unsaturated compounds (F) include for example compounds of the general formula I. Further particularly suitable unsaturated compounds (F) are those of the general formula F.1

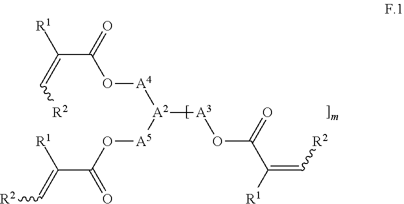

where
R¹ and R² are the same or different and are independently selected from hydrogen and C₁-C₁₀-alkyl,
m is an integer from 0 to 2 and preferably 1;
A² is CH₂ or —CH₂—CH₂— or R⁸—CH or para-C₆H₄ when m=0, CH, C—OH, C—O—C(O)—CH═CH₂, C—O—CO—C(CH₃)═CH₂, R⁸—C or 1,3,5-C₆H₃ when m=1,
   and carbon when m=2;
R⁸ is selected from C₁-C₄-alkyl, such as for example n-C₄H₉, n-C₃H₇, iso-C₃H₇ and preferably C₂H₅ and CH₃,
   or phenyl,
A³, A⁴ and A⁵ are the same or different and are each selected from C₁-C₂₀-alkylene, such as for example —CH₂—, —CH(CH₃)—, —CH(C₂H₅)—, —CH(C₆H₅)—, —(CH₂)₂—, —(CH₂)₃—, —(CH₂)₄—, —(CH₂)₅—, —(CH₂)₆—, —(CH₂)₇—, —(CH₂)₈—, —(CH₂)₉—, —(CH₂)₁₀—, —CH(CH₃)—(CH₂)₂—CH(CH₃)—; cis- or trans-C₄-C₁₀-cycloalkylene, such as for example cis-1,3-cyclopentylidene, trans-1,3-cyclopentylidene cis-1,4-cyclohexylidene, trans-1,4-cyclohexylidene; C₁-C₂₀-alkylene, in each of which from one up to seven carbon atoms which are each nonadjacent are replaced by oxygen, such as for example —CH₂—O—CH₂—, —(CH₂)₂—O—CH₂—, —(CH₂)₂—O—(CH₂)₂—, —[(CH₂)₂—O]₂—(CH₂)₂—, —[(CH₂)₂—O]₃—(CH₂)₂—;
   C₁-C₂₀-alkylene which is substituted by up to 4 hydroxyl groups, and in which from one up to seven carbon atoms which are each nonadjacent are replaced by oxygen, such as for example —CH₂—O—CH₂—CH(OH)—CH₂—, —CH₂—O—[CH₂—CH(OH)—CH₂]₂—, —CH₂—O—[CH₂—CH(OH)—CH₂]₃—;
   C₆-C₁₄-arylene, such as for example para-C₆H₄.

Particularly preferred examples of compounds of the general formula F.I are trimethylolpropane tri(meth)acrylate, tri(meth)acrylate of triply ethoxylated trimethylolpropane, pentaerythritol tri(meth)acrylate and pentaerythritol tetra(meth)acrylate.

Further very useful representatives of unsaturated compounds (F) are ethylene glycol di(meth)acrylate, diethylene glycol di(meth)acrylate, triethylene glycol di(meth)acrylate, propylene glycol (meth)acrylate, dipropylene glycol di(meth)acrylate and tripropylene glycol di(meth)acrylate.

Further very useful representatives of unsaturated compounds (F) are partially or exhaustively (meth)acrylated polyols such as for example partially or exhaustively (meth)acrylated dimeric trimethylolpropane, partially or exhaustively (meth)acrylated dimeric trimethylolethane, partially or exhaustively (meth)acrylated dimeric pentaerythritol.

For example, a total of up to 100% by weight, based on the sum total of (A) and (B), of unsaturated compound (F) can be added, preferably up to 50% by weight and more preferably up to 25% by weight.

Aqueous dispersions according to the present invention are very useful as or for producing formulations for dyeing or printing substrates, for example for producing dyeing liquors for pigment dyeing or for producing print pastes for pigment printing. The present invention therefore further provides for the use of aqueous dispersions according to the present invention as or for producing formulations for dyeing or printing substrates. The present invention similarly provides a process for dyeing or printing substrates by utilizing at least one aqueous dispersion according to the present invention.

Useful substrate materials include:

cellulosic materials such as paper, board, card, wood and woodbase, which may each be lacquered or otherwise coated,

metallic materials such as foils, sheets or workpieces composed of aluminum, iron, copper, silver, gold, zinc or alloys thereof, which may each be lacquered or otherwise coated,

silicatic materials such as glass, porcelain and ceramic, which may each be coated, polymeric materials of any kind such as polystyrene, polyamides, polyesters, polyethylene, polypropylene, melamine resins, polyacrylates, polyacrylonitrile, polyurethanes, polycarbonates, polyvinyl chloride, polyvinyl alcohols, polyvinyl acetates, polyvinylpyrrolidones and corresponding copolymers including block copolymers, biodegradable polymers and natural polymers such as gelatin,

comestibles and parts of comestibles in particular eggshells,

leather—both natural and artificial—in the form of smooth leather, nappa leather or suede leather, comestibles and cosmetics, and in particular textile substrates such as fibers, yarns, threads, knits, wovens, nonwovens and garments composed of polyester, modified polyester, polyester blend fabric, cellulosic materials such as cotton, cotton blend fabric, jute, flax, hemp and ramie, viscose, wool, silk, polyamide, polyamide blend fabric, polyacrylonitrile, triacetate, acetate, polycarbonate, polypropylene, polyvinyl chloride, blend fabric such as for example polyester-polyurethane blend fabric (e.g. Lycra®), polyethylene-polypropylene blend fabric, polyester microfibers and glass fiber fabric.

The substrates may optionally be in a pretreated and/or precoated state in that, for example, self-supporting plastics sheets can be corona discharge treated or precoated with a primer before application.

Plastics particularly worth highlighting include polycarbonate, polyethylene, for example PE, HDPE, LDPE, polypropylene, for example PP, oriented PP (OPP), biaxially oriented PP (BOPP), polyamide, for example Nylon®, and polyethylene terephthalate (PET).

Preferred substrates are paper, including in particular newsprint, paperboard, cardboard, polyester-containing self-supporting plastics sheets, polyethylene-containing self-supporting plastics sheets and polypropylene-containing self-supporting plastics sheets and also glass. Self-supporting plastics sheets may optionally also be metalized.

Printing inks according to the present invention for printing processes may comprise further admixtures (G) of the kind which are customary especially for aqueous printing inks and in the printing and coatings industries. Examples include preservatives such as for example 1,2-benzisothiazolin-3-one (commercially available as Proxel brands from Avecia Lim.) and its alkali metal salts, glutaraldehyde and/or tetramethylol-acetylenediurea, Protectols®, antioxidants, degassers/defoamers such as for example acetylenediols and ethoxylated acetylenediols, which typically comprise from 20 to 40 mol of ethylene oxide per mole of acetylenediol and may at the same time also have a dispersing effect, viscosity regulators, flow agents, wetters (for example wetting surfactants based on ethoxylated or propoxylated fatty or oxo alcohols, propylene oxide-ethylene oxide block copolymers, ethoxylates of oleic acid or alkylphenols, alkylphenol ether sulfates, alkylpolyglycosides, alkyl phosphonates, alkylphenyl phosphonates, alkyl phosphates, alkylphenyl phosphates or preferably polyethersiloxane copolymers, especially alkoxylated 2-(3-hydroxypropyl)heptamethyl-trisiloxanes, which generally comprise a block of 7 to 20 and preferably 7 to 12 ethylene oxide units and a block of 2 to 20 and preferably 2 to 10 propylene oxide units and may be comprised in the colorant preparations in amounts from 0.05% to 1% by weight), anti-settlers, luster improvers, glidants, adhesion improvers, anti-skinning agents, delusterants, emulsifiers, stabilizers, hydrophobicizers, light control additives, hand improvers, antistats, bases such as for example triethanolamine or acids, specifically carboxylic acids such as for example lactic acid or citric acid to regulate the pH. When these agents are a constituent part of present invention printing inks for printing processes, their total amount will generally be 2% by weight and especially 1% by weight, based on the weight of the present invention's colorant preparations and especially of the present invention printing inks for printing processes.

Useful compounds (G) also include styrene-acrylate copolymers comprising copolymers obtainable by free-radical polymerization which may comprise as monomers in interpolymerized form

(i) at least one vinylaromatic monomer, preferably selected from the group consisting of styrene and alpha-methylstyrene, more preferably styrene,

(ii) acrylic acid or methacrylic acid, preferably acrylic acid, and

(iii) optionally at least one C₁ to C₈-alkyl ester of acrylic acid or methacrylic acid, herein referred to as (meth)acrylic acid, preferably acrylic acid,

(iv) optionally monomers other than those mentioned under (i) to (iii) which are free-radically polymerizable, preferably 2-hydroxyethyl (meth)acrylate, acrylonitrile, acrylamide.

Preferred monomers (iii) are methyl acrylate, ethyl acrylate, n-butyl acrylate, 2-ethyl-hexyl acrylate, n-octyl acrylate, methyl methacrylate, ethyl methacrylate and n-butyl methacrylate.

Such copolymers can have a number average molecular weight Mw, determined by gel permeation chromatography in THF as solvent and polystyrene as standard, from 1000 to 1 500 000.

Typically, they have the following construction:

monomers (i): 20-80% by weight of styrene and/or alpha-methylstyrene

monomers (iI): 1-45% by weight of acrylic acid and 0-10% by weight of methacrylic acid, and

monomers (iII): 0-30% by weight of n-butyl acrylate, 0-30% by weight of 2-ethylhexyl acrylate.

Such copolymers are preferably obtainable via bulk polymerization and emulsion polymerization, more preferably via bulk polymerization.

Present invention printing inks for printing processes may further comprise a further photoinitiator other than the photoinitiator (E) which can be used in the preparation of aqueous dispersion according to the present invention, but is selected from the photoinitiators recited above.

Present invention printing inks for printing processes in one embodiment of the present invention have a dynamic viscosity in the range from 10 to 2000 mPa·s, preferably from 10 to 1000 mPa·s, and more preferably from 10 to 500 mPa·s and most preferably from 10 to 150 mPa·s, measured at 23° C. in accordance with German standard specification DIN 53018.

To adjust the viscosity, it may be necessary to add a thickener to the printing ink to adjust the viscosity.

The surface tension of present invention printing inks for printing processes in one embodiment of the present invention is in the range from 25 to 70 mN/m and especially in the range from 30 to 60 mN/m, measured at 25° C. in accordance with German standard specification DIN 53993.

The pH of present invention printing inks for printing processes in one embodiment of the present invention is in the range from 5 to 10 and preferably in the range from 7 to 10.

Present invention printing inks for printing processes have altogether advantageous performance characteristics, good drying performance, and produce printed images of high quality, i.e., of high brilliance and depth of shade and also high dry rub, light, water and wet rub fastness. They are particularly useful for printing coated and plain paper and also carboard and PE/PP/PET self-supporting sheets. It is a particular advantage of the printing inks of the present invention that their residues on printing rollers and printing plates, whether from a preceding printing operation or else have dried after interruption of the printing operation, exhibit improved redissolving. Such improved redissolving is particularly advantageous for the letterpress process but not just there. A further aspect of the present invention is a process for producing present invention printing inks for printing processes. The present invention's process for producing printing inks for printing processes comprises mixing at least one aqueous dispersion according to the present invention, water and if appropriate at least one admixture (G) with one another, for example in one or more steps.

Useful mixing techniques include for example stirring and intensive shaking and also dispersing, for example in ball mills or stirred ball mills.

The order of addition when mixing aqueous dispersion according to the present invention, water, if appropriate (C), if appropriate (D), if appropriate (E), if appropriate (F) and if appropriate (G) is as such not critical.

It is accordingly possible, in one preferred version of the present invention, first for at least one polyurethane (A) to be synthesized, then dispersed with pigment (B) and thereafter mixed with one or more of the desired additives additional (A), (C), (D), (E), (F) and/or (G) and, before or after the mixing, thinned with water.

It is possible, in one version of the present invention, first for at least one polyurethane (A) to be synthesized, then dispersed with pigment (B) and thereafter mixed with one or more of the desired additives (C), (D), (E), (F) and/or (G) and, before or after the mixing, thinned with water.

In another version of the present invention, (a) at least one polyurethane (A) and at least one polyurethane (D) are synthesized, then mixed with polymerization inhibitor (C) and dispersed with (B), thinned with water and mixed if appropriate with one or more of the desired additives (E), (F) and/or (G).

In another version of the present invention, at least one polyurethane (A) is synthesized in the presence of polymerization inhibitor (C) and then dispersed with pigment (B) and at least one of the desired additives (D) (E), (F) and (G).

In another version of the present invention, at least one polyurethane and also polyurethane (A) and at least one polyurethane (D) are synthesized in the presence of polymerization inhibitor (C) and then dispersed with pigment (B) and at least one of the desired additives (E), (F) and (G).

It is possible, in a further version, first for at least one styrene-acrylate copolymer (G) to be synthesized, then dispersed with pigment (B) and thereafter mixed with at least one polyurethane (A) and also optionally with one or more of the desired additives (C), (D), (E) and/or (F) and, before or after the mixing, thinned with water.

A further aspect of the present invention is a process for printing sheetlike or three-dimensional, preferably sheetlike, substrates by a printing process other than an ink jet process using at least one printing ink according to the present invention. A preferred version of the inventive printing process comprises printing at least one printing ink of the present invention onto a substrate and then treating with actinic radiation.

Printing processes in which the printing inks of the present invention can be used are preferably offset printing, letterpress, flexographic printing, gravure printing and intaglio printing, more preferably flexographic printing and gravure printing.

In the so-called mechanical printing processes such as offset printing, letterpress, flexographic printing or intaglio printing, the printing ink is transferred to the printing stock by a printing plate which is inked with the printing ink being brought into contact with the printing stock. Printing inks for these applications typically comprise solvents, colorants, binders and also, if appropriate, various additives. Binders serve to form the ink film and to anchor the constituents such as for example pigments or fillers in the ink film. Depending on their consistency, printing inks for these applications typically comprise between 10% and 50% by weight of binder.

Printing lacquers are either applied to the printing stock as a primer or after the printing operation to the printed printing stock as a coating. Printing lacquers are used for example to protect the printed image, to improve the adhesion of the printing ink to the printing stock, or for esthetic purposes. They are typically applied in-line by means of a lacquering unit on the printing machine.

Printing lacquers do not contain any colorants but otherwise generally have a similar composition to printing inks.

Printing inks for mechanical printing processes comprise so-called pasty printing inks of high viscosity for offset and letterpress printing and also so-called fluid printing inks of comparatively low viscosity for flexographic and intaglio printing.

In a preferred embodiment of the present invention, flexographic printing can be effected for example by printing the optionally pretreated substrate to be coated with differently pigmented printing inks of the present invention in succession at individual printing stations. Between the individual printing stations it is preferable for an at least partial drying and more preferably complete drying to take place.

The individual printing stations plus drying stations are preferably disposed around a central roll, but it is also possible to transport the substrate in each individual printing station via direction-changers over one roll in each case.

The final printed image after passage through all printing stations is dried and electron beam cured to completion.

The printing inks and lacquers of the present invention may optionally comprise further additives and auxiliary materials. Examples of additives and auxiliary materials are fillers such as calcium carbonate, aluminum oxide hydrate or aluminum silicate or magnesium silicate. Waxes enhance the abrasion resistance and serve to enhance glideability.

Examples are, in particular, polyethylene waxes, oxidized polyethylene waxes, petroleum waxes or ceresin waxes. Fatty acid amides can be used to enhance surface smoothness.

Plasticizers serve to enhance the elasticity of the dried film. Examples are phthalic esters such as dibutyl phthalate, diisobutyl phthalate, dioctyl phthalate, citric esters or esters of adipic acid. Dispersant auxiliaries can be used to disperse the pigments. In the case of the fluid printing inks and printing lacquers of the present invention, it is advantageously possible to omit adhesion promoters without thereby foreclosing the use of adhesion promoters. The total amount of all additives and auxiliary materials typically does not exceed 20% by weight, based on the sum total of all constituents, and is preferably in the range from 0% to 10% by weight.

The layer thickness in which the printing inks of the present invention are applied to the substrate differs with each printing method and can typically be up to 10 μm, preferably in the range from 0.1 to 8 μm, more preferably in the range from 0.2 to 7 μm, even more preferably in the range from 1 to 5 μm and particularly in the range from 1 to 4 μm.

Typical printing ink layer thicknesses are 2-4 μm for letterpress/flexographic printing, 1-2 μm for offset printing, 2-8 μm for intaglio printing and 20-30 μm for screen printing.

Present invention printing inks for printing processes are curable by actinic radiation. Actinic radiation having a wavelength range from 200 nm to 450 nm is useful for example. Actinic radiation having an energy in the range from 70 mJ/cm² to 2000 mJ/cm² is useful for example. Actinic radiation may advantageously be applied continuously or in the form of flashes for example.

A preferred embodiment of the present invention comprises effecting the curing of the printing inks by means of electron radiation in suitable electron flash devices, for example at an energy in the range from 70 to 300 keV, preferably from 150 to 200 keV. One advantage of performing the curing by means of electron radiation is that the printing inks thus cured are generally more resistant to rubbing than printing inks cured with UV light.

When curing is effected by means of electron radiation, the printing ink of the present invention preferably does not comprise any photoinitiator (E). This has the advantage that no migratable photoinitiator constituents remain in the coating which have been formed by irradiation. This is particularly of advantage when the coatings are intended for food contact.

The distance of the electron flash devices to the printing surface is between 1 and 100 cm, preferably 5 to 50 cm.

It will be appreciated that it is also possible to use two or more sources of radiation for the curing in order to achieve the radiation dose required for optimum curing.

In one embodiment of the present invention, the substrate materials after printing and before treatment with actinic radiation can be interdried, for example thermally or with IR radiation. Examples of suitable conditions are temperatures ranging from 30 to 120° C. for a period from 10 seconds to 24 hours, preferably from one up to 30 min, more preferably up to 5 min. Useful IR radiation includes for example IR radiation in a wave region above 800 nm. Useful interdrying apparatuses include for example drying cabinets including vacuum drying cabinets for thermal interdrying, and also IR lamps.

Similarly, the heat evolved upon application of actinic radiation can have an interdrying effect.

Invention printing inks and prints obtained using invention printing inks, however, are also curable thermally, with or without the action of actinic radiation. For instance, prints obtained using invention printing inks are fixable by drying at 25 to 150° C., preferably 100 to 150° C., more preferably 120 to 150° C.

In one preferred embodiment, the irradiating can also be carried out under exclusion of oxygen or oxygen-depleted atmosphere, for example at an oxygen partial pressure of less than 18 kPa, preferably 0.5-18 kPa, more preferably 1-15 kPa, even more preferably 1 to 10 kPa and particularly 1-5 kPa, or under inert gas atmosphere. Useful inert gases are preferably nitrogen, noble gases, carbon dioxide, water vapor or combustion gases. The oxygen partial pressure can also be reduced by lowering the ambient pressure.

One preferred embodiment of the present invention comprises a first step of dispersing at least one present invention polyurethane (A) and at least one pigment (B) to form initially a pigment concentrate which in a second step is then mixed by addition of a styrene-acrylate copolymer, as described under (G), as non-radiation-curable binder to form a simple printing ink. This can then be mixed in a third step by addition of the components (C), (D), (F) and/or (G) to form the actual printing ink which in a fourth step is applied to the desired substrate and in a fifth step is electron beam cured.

It is also possible, in a first step, by dispersing at least one styrene-acrylate copolymer as described under (G) and at least one pigment (B) to initially produce a pigment concentrate which in a second step is then mixed to form a simple printing ink by addition of at least one polyurethane (A) of the present invention. This simple printing ink can then be mixed in a third step, by addition of the components (C), (D), (F) and/or (G), to form the actual printing ink which in a fourth step is applied to the desired substrate and in a fifth step is electron beam cured.

In a further embodiment of the present invention, two or more and preferably three or more different present invention printing inks for printing processes can be combined into sets, in which case different printing inks according to the present invention each comprise different pigments each having a different color.

The present invention further provides at least partially enveloped pigments produced by dispersing at least one pigment (B), at least one polymerization inhibitor (C) and at least one polyurethane (A), said polyurethane (A) being obtainable by reaction of
(a) 15% to 70% by weight and preferably 30% to 60% by weight of di- or polyisocyanate comprising on average from 1 to 10 allophanate groups and on average from 1 to 10 C—C double bonds per molecule, and optionally
(b) 0% to 60% by weight and preferably to 20% by weight of further di- or polyisocyanate, with
(c) 5% to 50% by weight and preferably 30% to 50% by weight of compound having at least two isocyanate-reactive groups,

weight % ages being based on total polyurethane (A).

The present invention provides specifically at least partially enveloped above-described pigments wherein said di- or polyisocyanate (a) is prepared by reaction of at least one di- or polyisocyanate (a1) with at least one compound of the general formula I

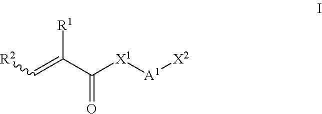

where
R¹ and R² are the same or different and are independently selected from hydrogen and C₁-C₁₀-alkyl,
X¹ is selected from oxygen and N—R³,
A¹ is selected from C₁-C₂₀-alkylene which is unsubstituted or singly or multiply substituted by C₁-C₄-alkyl, phenyl or O—C₁-C₄-alkyl, and in which one or more nonadjacent CH₂ groups may be replaced by oxygen;
X² is selected from hydroxyl and NH—R³,
R³ is in each occurrence the same or different and selected from hydrogen, C₁-C₁₀-alkyl and phenyl.

The present invention provides specifically pigments at least partially enveloped by polyurethane (A) wherein polyurethane (A) is prepared by reaction of
(a) 15% to 70% by weight of di- or polyisocyanate comprising on average from 1 to 10 allophanate groups and on average from 1 to 10 C—C double bonds per molecule, and optionally
(b) nil to 60% by weight of further di- or polyisocyanate, with
(c) 5% to 50% by weight of compound having at least two isocyanate-reactive groups, and
(d) at least one compound of the general formula I

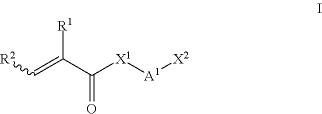

where
R¹ and R² are the same or different and are independently selected from hydrogen and C₁-C₁₀-alkyl,
X¹ is selected from oxygen and N—R³,
A¹ is selected from C₁-C₂₀-alkylene which is unsubstituted or singly or multiply substituted by C₁-C₄-alkyl, phenyl or O—C₁-C₄-alkyl, and in which one or more nonadjacent CH₂ groups may be replaced by oxygen;
X² is selected from hydroxyl and NH—R³,
R³ is in each occurrence the same or different and selected from hydrogen, C₁-C₁₀-alkyl and phenyl.

A process for producing at least partially enveloped pigments according to the present invention is described above and likewise forms part of the subject matter of the present invention.

At least partially enveloped pigments according to the present invention are winnable for example from aqueous dispersions according to the present invention by removing the water, for example by drying, freeze drying, filtration or a combination thereof.

At least partially enveloped pigments according to the present invention are particularly useful for producing printing inks for printing processes.

The present invention further provides polyurethanes (A) prepared by reaction of
(a) 15% to 70% by weight, preferably 30% to 60% by weight, of di- or polyisocyanate comprising on average from 1 to 10 allophanate groups and on average from 1 to 10 C—C double bonds per molecule, and
(b) optionally nil to 60% by weight, preferably to 20% by weight, of further di- or polyisocyanate,
(c) 5% to 50% by weight, preferably 30% to 50% by weight, of compound having at least two isocyanate-reactive groups, and optionally
(d) at least one compound of the general formula I.

Weight % ages are all based on total polyurethane (A) of the present invention.

In one embodiment of the present invention, polyurethane (A) of the present invention has a double bond density in the range from 0.1 to 5 mol/kg of (A), preferably in the range from 0.5 to 3 mol/kg of (A) and most preferably in the range from 1 to 2 mol/kg of (A), determinable for example by determination of the hydrogenation iodine number and by ¹H NMR spectroscopy.

To improve the durability of polyurethane (A) of the present invention, it is admixed with at least one polymerization inhibitor (C) during or immediately after synthesis.

A process for producing polyurethanes (A) according to the present invention is described above and likewise forms part of the subject matter of the present invention.

Polyurethanes (A) according to the present invention are particularly useful for producing printing inks according to the present invention and for producing aqueous dispersions according to the present invention.

The invention is illustrated by working examples.

### General Preliminaries:

The NCO content was in each case monitored titrimetrically in accordance with German standard specification DIN 53185.

The degree of envelopment of pigments according to the present invention was determined by transmission electron microscopy using the freeze fracture technique.

Solids content: %ages in the realm of the present invention are all % by weight. Solids contents in the realm of the present invention are all determined by drying at 150° C. for 30 minutes.

Dynamic viscosity was in each case determined at room temperature.
I. Preparation of Inventive at Least Partially Enveloped Pigments
I.1. Preparation of Inventive Polyurethane
I.1.1 Preparation of Diisocyanate (a.1), Which Comprises Allophanate Groups and C—C Double Bonds

### EXAMPLE 1.1

Of EP 1 144 476 B1 was repeated. Hexamethylene diisocyanate (HDI) (a.1.1) was mixed with 2-hydroxyethyl acrylate and nitrogen and heated to 80° C. in a stirred flask. 200 weight ppm of N,N,N-trimethyl-N-(2-hydroxypropyl)ammonium 2-ethylhexanoate

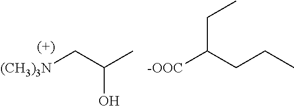

were added and thereafter the temperature was raised to 120° C. within half an hour. Thereafter, the resulting reaction mixture was maintained at 120° C. with continued stirring until the titrimetrically determined NCO content was 25% by weight, based on total reaction mixture. The reaction was stopped by addition of 250 weight ppm of di(2-ethylhexyl) phosphate, based on (a.1.1). The mixture thus obtainable was subsequently freed of unconverted HDI in a thin film evaporator at 135° C. and 2.5 mbar. The thus obtainable diisocyanate (a.1) had an NCO content of 15% by weight, a dynamic viscosity of 1200 mP·s at 23° C. The residual HDI content was below 0.5% by weight. The C—C double bond density was 2 C—C double bonds per molecule.
I.1.2 Conversion of (a.1) to Inventive Polyurethane (A.2)

63.1 g of a polyesterdiol having a molecular weight M_{w} of 800 g/mol, prepared by polycondensation of isophthalic acid, adipic acid and 1,4-dihydroxymethylcyclohexane (isomeric mixture) in a molar ratio of 1:1:2, were heated to 120° C. The resultant melt was transferred to a 2 l reactor equipped with stirrer, reflux condenser, gas inlet tube and dropping funnel, and heated to 130° C. under nitrogen. Once the polyesterdiol was present as a clear melt, it was cooled down to 80° C. with stirring. Thereafter, 8.2 g of neopentylglycol and 26.8 g of 2,2-dimethylolpropionic acid and also 0.3 g of polymerization inhibitor (C.1) and 0.15 g of polymerization inhibitor (C.2) were added before cooling down to 60° C.

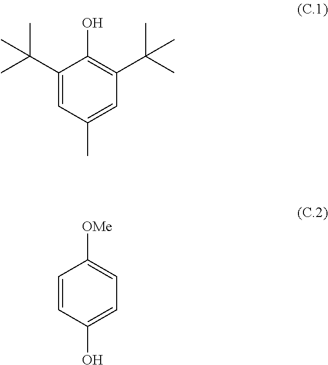

Thereafter, 297.5 g of tetrahydrofuran (THF), 185.6 g of diisocyanate (a.1) and 13.7 g of hexamethylene diisocyanate (HDI) (a.2.1) were added. This was followed by the addition of 5.95 g of triethylamine (2% by weight based on total solids) and stirring at 60° C. until the titrimetrically determined NCO content had decreased to 0.7% by weight, based on total reaction mixture. Thereafter, an ice bath was used to cool the reaction mixture down to room temperature, and the reaction was stopped by addition of 16.8 g of diethanolamine dissolved in 16.8 g of THF. The acid groups were subsequently neutralized with 20.2 g of triethylamine, dissolved in 20.2 g of THF. Finally, the polymer solution in tetrahydrofuran was admixed with 1004 g of water and the organic solvent was removed under reduced pressure. The double bond density of the resulting polymer A.2 (Mₙ=3400 g/mol; M_{w}=13 300 g/mol) was 1.92 mol of double bonds/kg of polyurethane. The aqueous dispersion had a solids content of 28.9%. The glass transition temperature of inventive polyurethane (A.2) was 34° C.
1.2. Production of Inventive Aqueous Dispersions of at Least Partially Enveloped Pigments, Example 1

Inventive aqueous dispersions were produced on a Skandex shaking apparatus using 60 g of glass balls (0.25-0.5 mm in diameter). The recipes are summarized in Table 1. After the ingredients and the glass balls have been weighed into the Skandex, the resulting mixture was shaken at 4000 rpm for 30 min/kg.

Inventive aqueous pigment dispersions WP.1 and WP.2 were obtained (Tab. 1).

TABLE 1
Ingredients and recipe parameters for inventive
aqueous pigment concentrates WP.1 and WP.2

| Ingredient | WP.1 | WP.2 (Comparative) |
|---|---|---|
| JONCRYL ® HPD 296 (35.5%) | — | 32.4 |
| A.2 (28.9%) | 38.1 | — |
| Tego ® Foamex 810 | 0.5 | 0.5 |
| Water | 17.4 | 21.1 |
| Pigment | 44.0 | 46.0 |
| Pigment/Binder ration | 4:1 | 4:1 |
| Pigment content (% by wt.) | 44.0 | 46.0 |
| Power (W) | 400 | 700 |
| Temperature (° C.) | 30 | 40 |
| Viscosity (mPa · s) | | |
| Spindle #3/Speed 6 | 1540 | 300 |

Amounts of ingredients are reported in g.
Joncryl HPD296 is a high performance pigment dispersant with very good grind characteristics. It constitutes an optimized formulation of styrene-acrylate oligomers with polymeric additives.
Foamex from Tego is a conventional defoamer which destroys the air bubbles which appear at high shearing forces.
The pigment used was a copper phthalocyanine blue from BASF (PB 15.3).

### FORMULATION EXAMPLE 2

### Preparation of Printing Inks from Pigment Concentrates WP.1 and WP.2

The pigment concentrates were mixed with additives and, where appropriate, a photoinitiator to prepare the inventive printing inks PT.1 and PT.2. The comparative produce used was a printing ink PT.3 without radiation-curable polyurethane (Tab. 2).

TABLE 2
Recipe parameters and properties of inventive
aqueous pigment concentrates PT.1 and PT.2 and
PT.4 and of comparative printing ink PT.3.

| Ingredients | PT.1 | PT.2 | PT.3 | PT.4 |
|---|---|---|---|---|
| Pigment concentrate | WP.1 | WP.1 | WP.2 | WP.2 |
| | 34.1 | 34.1 | 32.6 | 32.6 |
| JONCRYL ® 2647 | — | — | 61.4 | — |
| A.2 (28.9%) | 59.9 | 59.9 | — | 61.4 |
| JONCRYL ® WAX 35 | 5.0 | 5.0 | 5.0 | 5.0 |
| TegoWet ® 500 | 1.0 | 1.0 | 1.0 | 1.0 |
| Darocur ® 1173 | 1.73 | — | — | 1.73 |
| (photoinitiator) | | | | |
| Viscosity (mPa · s) | 120 | 120 | 355 | 125 |

Amounts of ingredients are reported in g.
Joncryl 2647 is a conventional polymeric binder (styrene-acrylate dispersion) for flexographic and gravure printing processes. It is not radiation-curable and not self-crosslinking. The function of the binder is to fix the constituents of the formulation to the substrate.
TegoWet is a wetting agent which ensures superior wetting of the formulation on coated substrates or nonabsorbent substrates.
Joncryl Wax 35 is a polyethylene wax emulsion which improves the rubfastnesses of the printed substrates.

Rubfastnesses of printed printing inks from formulation example 2

Inventive printing inks PT.1 and PT.2 and PT.4 and also comparative printing ink PT.3 were printed at 140 L/l onto Leneta 2A opacity test cards (cardboard).

Printing inks PT.1 and PT.4, comprising a photoinitiator, were fixed by exposure to actinic radiation. Printing ink PT.2 did not comprise any photoinitiator and was merely fixed thermally by exposure to actinic radiation and thereby induced heating. In both cases, the result was a covalent crosslinking of the double bonds of the radiation-curable polyurethane. Comparative liquid ink PT.3 comprised neither radiation-curable polyurethane nor photoinitiator and therefore was fixed by physical drying (1 minute at 60° C.) only.

Irradiation with actinic radiation was performed using an M40-2-Tr-SS UV irradiator from IST with two different UV radiators (gallium M400 U1A and mercury M400 U1). The substrates were exposed twice in a UV exposure unit at a speed of 5 meters per minute using 650 mJ/cm² each time.

This method was used to obtain the inventive printed substrates S.1 and S.2 and S.4 (printing inks PT.1 and PT.2 and PT.4) and also comparative substrate S.3 (PT.3), for which the rubfastnesses (dry) were determined thereafter. This was done by rubbing a cotton strip on the printed substrate 200 times using a SATRA test apparatus (from SATRA) and subsequently assessing the degree rubbed off by visual inspection. The degree rubbed off is reported in percent of the coating which remains (Tab. 3).

TABLE 3
Fastnesses of substrates S.1-S.2 and S.4 printed according
to the invention and of comparative substrate S.3.

| | Printing | | Rubfastness |
|---|---|---|---|
| Substrate | ink | Curing | dry |
| S.1 | PT.1 | UV-induced fixing | 95 |
| S.2 | PT.2 | Thermal fixing | 90 |
| S.3 | PT.3 | Physical drying | 50 |
| S.4 | PT.4 | UV-induced fixing | 90 |

It is apparent that printing ink PT.3, utilizing no polyurethane (A) to prepare the pigment concentrate nor as binder, gives the lowest rubfastnesses.

It can be an embodiment of the present invention to use the polyurethane (A) as binder at least when the pigment was dispersed in a conventional dispersant (pigment concentrate WP.2 and printing ink PT.4).

Particular preference is given to an embodiment of the present invention wherein the polyurethane (A) is used to disperse the pigment and envelops the latter wholly or partly, irrespective of which binder is used to prepare the printing ink. This embodiment does give good results in purely thermal curing (PT.2), but can be still further improved on using UV curing (PT.1). Curing by electron beam curing is preferred in particular.

In a particularly preferred embodiment of the present invention a polyurethane (A) is used both in the dispersing of the pigment and as a binder to prepare the printing ink. This embodiment does give good results in purely thermal curing, but can be still further improved on using UV curing in the presence of photoinitiators (PT.1). Particular preference is given to curing by electron beam curing, for which photoinitiators may preferably also be omitted.
I.3.1. Preparation of Aqueous Dispersions of at Least Partially Enveloped Pigments, Example Featuring WP.3

An aqueous dispersion was homogenized using a Dispermat at 6000 rpm for 10 minutes. The homogenisate was subsequently admixed in a ball mill (Dispermat SL) with 100 g of zirconium balls (diameter 0.8-1.0 mm) and processed at 32° C. for 30 minutes (pump power 788 watts).

This gave aqueous pigment concentrate WP.3 (Tab. 4).

TABLE 4
Ingredients for aqueous pigment concentrate WP.3

| Ingredients | WP.3 |
|---|---|
| JONCRYL ® HPD 296 (35.5%) | 32.8 |
| Tego ® Foamex 810 | 0.5 |
| Water | 22.6 |
| Pigment Black (Printex 55 Fluffy) | 44.1 |
| Viscosity (mPa · s), spindle #3 speed 12 | 7000 |

I.3.2. Preparation of Printing Inks from Pigment Concentrate WP.3

Pigment concentrate WP.3 was mixed with additives to prepare inventive printing ink PT.5.

TABLE 5
Recipe parameters and properties of
inventive aqueous printing ink PT.5.

| Ingredients | PT.5 |
|---|---|
| Pigment concentrate WP.3 | 40.0 |
| A.2 (25.1%) | 52.0 |
| JONCRYL ® WAX 35 | 5.0 |
| Tego Foamex 1488 | 0.5 |
| Thickener | 3.0 |
| Viscosity (DIN 4 efflux time; in seconds) | 22 |

Amounts of ingredients are reported in g.
I.3.3. Rubfastnesses of Printed Printing Inks PT.5

Inventive printing ink PT.5 was flexographically printed at 70 L/l at 200 m/min onto freshly corona-treated polyethylene (4000 watts).

In the configuration without electron beam curing (thermal fixing) the printed substrates were thermally fixed with the aid of a drying station (60° C.) disposed on the printing roll and an open drying duct. In the configuration with electron beam curing, the thermal fixing operation is followed by electron beam curing (EZCure® electron beam curer from ESI, energy dose 30 kGy).

This method was used to obtain inventive printed substrate S.5 (printing ink PT.5, with electron beam curing) and also comparative substrate S.6 (printing ink PT.5 with thermal fixing), for which the rubfastnesses (wet) were subsequently determined. This was done by rubbing a water-drenched cotton strip 200 times on the printed substrate with the aid of a SATRA test apparatus (from SATRA) and subsequently assessing the degree rubbed off by visual inspection. The degree rubbed off was reported in percent of the coating which remains (Tab. 6). The comparative substrate showed complete ruboff after just 5 rubbing cycles.

TABLE 6
Fastnesses of substrate S.5 printed according to
the invention and of comparative substrate S.6.

| | Printing | | Rubfastness |
|---|---|---|---|
| Substrate | ink | Curing | wet |
| S.5 | PT.5 | Electron beam curing | 80 |
| S.6 | PT.5 | Thermal fixing | 0 |

1. A printing ink comprising an aqueous dispersion comprising at least one polyurethane (A), at least one pigment (B) and further comprising at least one polymerization inhibitor (C), wherein the at least one polyurethane (A) at least partially envelops the at least one pigment (B), said polyurethane (A) being obtained by a process comprising reacting
(a) 15% to 70% by weight of di- or polyisocyanate comprising on average from 1 to 10 allophanate groups and on average from 1 to 10 C—C double bonds per molecule, and optionally
(b) 0% to 60% by weight of further di- or polyisocyanate, with
(c) 5% to 50% by weight of compound having at least two isocyanate-reactive groups, based on polyurethane (A).

2. The printing ink according to claim 1 wherein said di- or polyisocyanate (a) is prepared by a process comprising reacting at least one di- or polyisocyanate (a1) with at least one compound of the general formula I 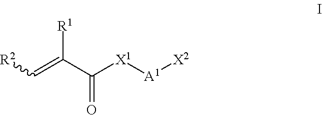
where
R¹ and R² are the same or different and are independently selected from hydrogen and C₁-C₁₀-alkyl,
X¹ is selected from oxygen and N—R³,
A¹ is selected from C₁-C₂₀-alkylene which is unsubstituted or singly or multiply substituted by C₁-C₄-alkyl, phenyl or O—C₁-C₄-alkyl, and in which one or more nonadjacent CH₂ groups may be replaced by oxygen;
X² is selected from hydroxyl and NH—R³,
R³ is in each occurrence the same or different and selected from hydrogen, C₁-C₁₀-alkyl and phenyl.

3. The printing ink according to claim 1 wherein at least one compound having at least two isocyanate-reactive groups (c) is selected from the group consisting of a 1,1,1-trimethylol-C₁-C₄-alkylcarboxylic acid, citric acid, a 2,2-dimethylol-C₁-C₄-alkylcarboxylic acid, a 2,2-dimethylol-C₁-C₄-alkylsulfonic acid acids, a poly-C₂-C₃-alkylene glycol glycols having on average from 3 to 300 C₂-C₃-alkylene oxide units per molecule, a hydrophilic polyamines having COOM or SO₃M groups, where M is selected from alkali metal ions and ammonium ions, and a polyesterdiol preparable by polycondensation of at least one aliphatic or cycloaliphatic diol with at least one aliphatic, aromatic or cycloaliphatic dicarboxylic acid.

4. The printing ink according to claim 1 further comprising at least one polyurethane (D) which is obtained by a process comprising reacting di- or polyisocyanate (b) with compound having at least two isocyanate-reactive groups (c).

5. The printing ink according to claim 4 wherein said pigment (B) is partially enveloped by polyurethane (D).

6. The printing ink according to claim 1 wherein said polyurethane (A) has a glass transition temperature T_{g} of not more than 60° C.

7. The printing ink according to claim 1 wherein said aqueous dispersion comprises at least one photoinitiator (E).

8. The printing ink according to claim 1 wherein the aqueous dispersion is cured by electron radiation in the absence of a photoinitiator (E).

9. The printing ink according to claim 1 wherein said polyurethane (A) is prepared by a process comprising reacting
(a) 15% to 70% by weight of di- or polyisocyanate comprising on average from 1 to 10 allophanate groups and on average from 1 to 10 C—C double bonds per molecule, and optionally
(b) 0% to 60% by weight of further di- or polyisocyanate, with
(c) 5% to 50% by weight of compound having at least two isocyanate-reactive groups, and optionally
(d) at least one compound of the general formula I, based on polyurethane (A).

10. (canceled)

11. A process for printing a substrate, which comprises printing a substrate with a printing ink as described in claim 1 in using a printing process other than ink jet printing.

12. The process according to claim 11 wherein the substrate is selected from the group consisting of paper, paperboard, cardboard, polyester-containing self-supporting plastics sheet, polyethylene-containing self-supporting plastics sheet and polypropylene-containing self-supporting plastics sheet, and glass.

13. The process according to claim 11 wherein the printing process is selected from the group consisting of offset printing, letterpress, flexographic printing, gravure printing and intaglio printing.

14. The process according to claim 11 comprising curing the printing inks which comprise no photoinititator by means of by electron radiation in suitable electron flash devices using an energy of 70 to 300 keV.

15. A method of forming a printing ink comprising mixing
at least one polyurethane (A),
at least one pigment (B) and
at least one polymerization inhibitor (C),
wherein the at least one polyurethane (A) at least partially envelops the at least one pigment (B), and said polyurethane (A) is obtained by a process comprising reacting
(a) 15% to 70% by weight of di- or polyisocyanate comprising on average from 1 to 10 allophanate groups and on average from 1 to 10 C—C double bonds per molecule, and optionally
(b) 0% to 60% by weight of further di- or polyisocyanate, with
(c) 5% to 50% by weight of compound having at least two isocyanate-reactive groups, based on polyurethane (A).

16. The method of forming a printing ink according to claim 15, wherein said di- or polyisocyanate (a) is prepared by a process comprising reacting at least one di- or polyisocyanate (a1) with at least one compound of the general formula I 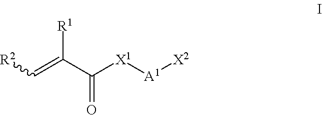
where
R¹ and R² are the same or different and are independently selected from hydrogen and C₁-C₁₀-alkyl,
X¹ is selected from oxygen and N—R³,
A¹ is selected from C₁-C₂₀-alkylene which is unsubstituted or singly or multiply substituted by C₁-C₄-alkyl, phenyl or O—C₁-C₄-alkyl, and in which one or more nonadjacent CH₂ groups may be replaced by oxygen;
X² is selected from hydroxyl and NH—R³,
R³ is in each occurrence the same or different and selected from hydrogen, C₁-C₁₀-alkyl and phenyl.

17. The method of forming a printing ink according to claim 15, wherein said polyurethane (A) is prepared by a process comprising reacting
(a) 15% to 70% by weight of di- or polyisocyanate comprising on average from 1 to 10 allophanate groups and on average from 1 to 10 C—C double bonds per molecule, and optionally
(b) 0% to 60% by weight of further di- or polyisocyanate, with
(c) 5% to 50% by weight of compound having at least two isocyanate-reactive groups, and optionally
(d) at least one compound of the general formula I, based on polyurethane (A).
